(19) United States
(12) Patent Application Publication
(10) Pub. No.: US 2009/0298233 A1
(43) Pub. Date: Dec. 3, 2009

(54) Method for Fabricating Semiconductor Elements

(75) Inventor: Chin-Ti Chen, Hsinchu (TW)

Correspondence Address: Eschweiler & Associates LLC;National City Bank Building, 629 Euclid Avenue, Suite 1000, Cleveland, OH, 44114, US

(73) Assignee: Powertech Technology Inc., Hsinchu (TW)

(21) Appl. No.: 12/240,499

(22) Filed: Sep. 29, 2008

(30) Foreign Application Priority Data
May 30, 2008 (TW) 097120269

(51) Int. Cl. H01L 21/56

(52) U.S. Cl. 438/114; 257/E21.502

(57) ABSTRACT

The present invention discloses a method for fabricating semiconductor elements, which comprises steps: providing a substrate having a wiring pattern on the upper surface thereon electrically connecting a wafer to the substrate for signal input and output; filling a resin into between the wafer and tire substrate to fix the wafer to the substrate; and singulating the combination of the wafer and the substrate into a plurality of semiconductor elements. Therefore, the present can simplify the fabrication process or semiconductor elements.

### BACKGROUND OF THE INVENTION

1. Field of the invention

The present invention relates to a method for fabricating semiconductor dements, particularly to a method for fabricating semiconductor elements, which can simplify the fabrication process.

2. Description of the Related Art

As the life cycles of consumable products are getting shorter and shorter, the semiconductor packaging industry has to make efforts to seek low-cost and high-efficiency new technologies to accelerate the progress of entering the market and satisfy the requirements of the market.

The flip-chip technology is usually used to fabricate semiconductor elements, and the steps thereof include die saw, die mount (die bond), underfilling, singulation, and inspection. Refer to FIG. 1a and FIG. 1b. A pre-cut wafer 10 is singulated into chips 30 with a cutting tool 20. Next, the chips 30 are arranged on a substrate 32 and electrically connect to the substrate 32 with metal bumps 34. Refer to FIG. 1c. Next, a glue 36 is filled into between the chips 30 and the substrate 32 to stick the chips 30 to the substrate 32. Alternatively, a resin encapsulant (not shown in the figure) is used to cover the chips 30 and the substrate 32 to prevent from humidity. Refer to FIG. 1d. Next, the substrate 32 having chips thereon is singulated into semiconductor elements 40. Then, the electric performance of the semiconductor elements 40 is inspected to discard the defective ones.

In the prior art after the wafer has been singulated into chips, the chips are sequentially arranged on the substrate one by one, which is a very time-consuming process. Further, the prior art needs two singulation processes—singulating the water and singulating the substrate with chips thereon, which also increases the fabrication time. Therefore, how to simplify the fabrication process of semiconductor elements is a problem the manufacturers desire to overcome.

### SUMMARY OF THE INVENTION

One objective of the present invention is to provide a method for fabricating semiconductor elements to solve the above-mentioned problems, wherein a wafer is directly stuck to and electrically connected to a substrate, and the water and substrate are simultaneously singulated, whereby the process of fabricating semiconductor elements is simplified.

Another objective of the present invention is to provide a method for fabricating semiconductor elements, wherein a wafer is directly stuck to and electrically connected to a substrate, whereby the fabrication process is exempted from positioning chips on a substrate one by one.

A further objective of the present invention is to provide a method for fabricating semiconductor elements, whereby the time and cost spent on singulating a wafer is saved.

To achieve the abovementioned objectives, one embodiment of the present invention proposes a method for fabricating semiconductor elements, which comprises steps: providing a substrate having a wiring pattern on the upper surface thereof; electrically connecting the substrate to a wafer for signal input and output: filling a resin into between the wafer and the substrate to fix the wafer to the substrate; and singulating the combination of the wafer and the substrate into a plurality of semiconductor elements.

### BRIEF DESCRIPTION OF THE DRAWINGS

FIGS 1a-1d are diagrams schematically showing a conventional method for fabricating semiconductor elements;

FIGS. 2a-2d are diagrams schematically showing a method for fabricating semiconductor elements according to one embodiment of the present invention:

FIG. 3 is a partially enlarged view schematically showing that a wafer is connected to a substrate with metal bumps according to another embodiment of the present invention;

FIG. 4 is a partially enlarged view schematically showing that BAG is formed on a substrate according to a further embodiment of the present invention; and

FIG. 5 is a flowchart of the method for fabricating semiconductor elements according to FIGS. 2a-2d.

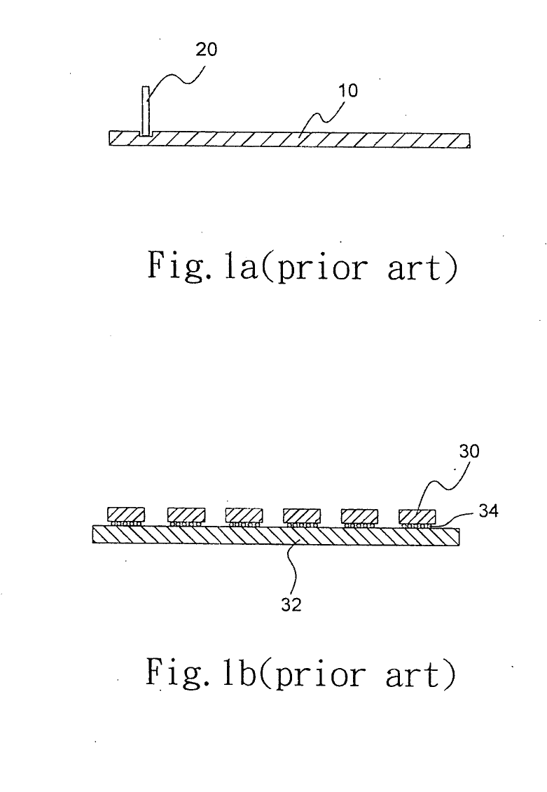

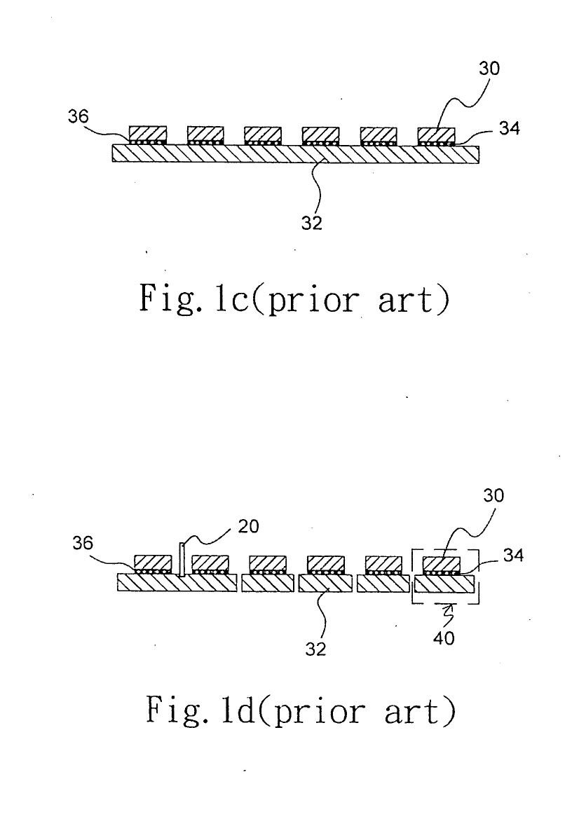

### DETAILED DESCRIPTION OF THE INVENTION

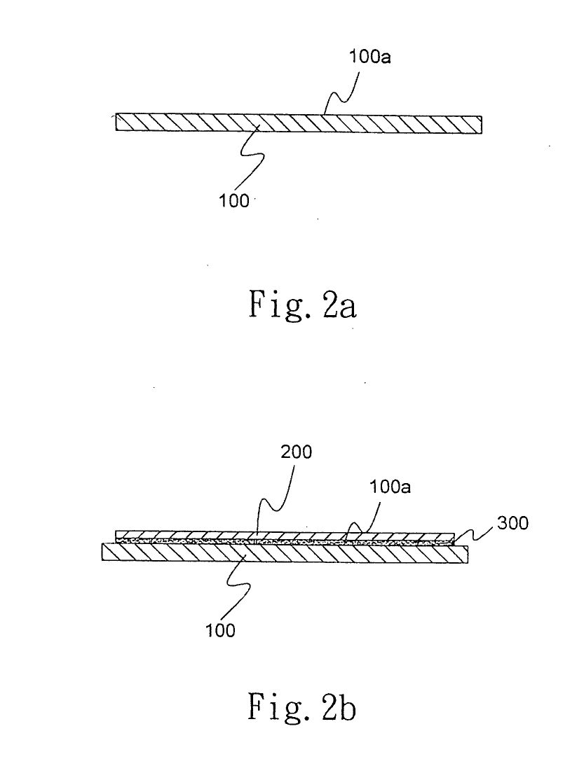

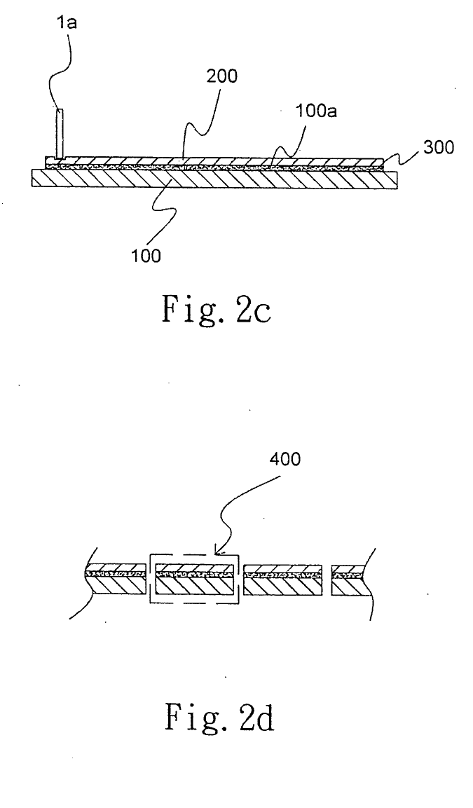

Refer to FIG. 2a to FIG. 2d diagrams schematically showing a method for fabricating semiconductor elements according to one embodiment of the present invention. As shown in FIG. 2a, a substrate 100 is provided, and the upper surface 100a of the substrate 100 has a wiring pattern (not shown in the drawings). Next, as shown in FIG. 2b, a wafer 200 is electrically connected to the substrate 100 for signal input and output; a resin 300 is applied to between, the chip 100 and the wafer 200, whereby the wafer 200 is fixedly installed on the substrate 100. Then, as shown in FIG. 2c and FIG. 2d, the combination of the substrate 100 and the wafer 200 is singulated into a plurality of semiconductor elements 400; for example, the combination, of the substrate 100 and the water 200 is singulated with a cutting tool 1a.

From the above description, it is known that the present invention is exempted from the step of cutting a water into chips but needs only one cycle of cutting to singulate the combination of the substrate and the wafer into a plurality of independent semiconductor elements. Therefore, the present invention can save the time and cost of cutting wafers and thus can simplify the fabrication process.

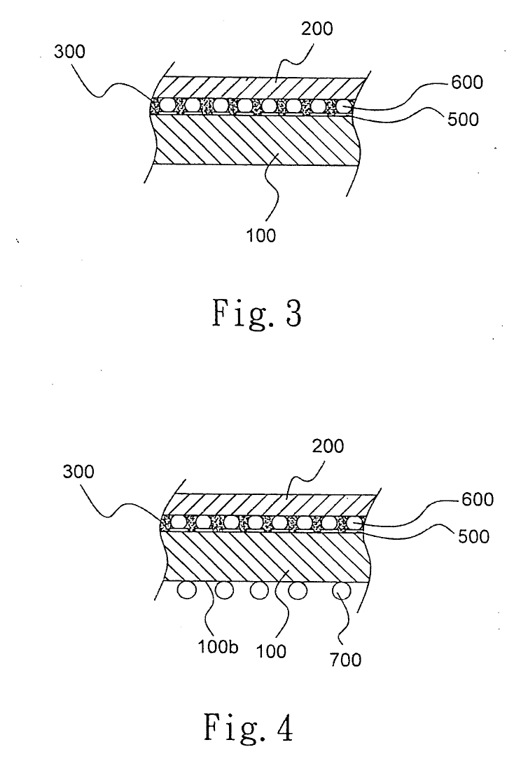

Refer to FIG. 3. In a preferred embodiment, the substrate 100 has a wiring pattern (not shown in the drawings) and contact pads 500, and the wafer 200 has a layer of arrayed circuits (not shown in the drawings) and a plurality of metal bumps 600, and the contact pads 500 of the substrate 100 are electrically connected to the metal bumps 600 of the wafer 200 by such as a thermal fusion method.

Further, the resin 300 is filled into between the substrate 100 and the wafer 200 by pressurization or capillarity to fix the substrate 100 and the wafer 200. Further, the resin 300 is a high-permittivity or high-thermal conductivity polymer, which can prevent the electric performance of semiconductor elements from being damaged.

In another preferred embodiment, the combination of the substrate and the wafer is singulated with a laser or a cutting tool along predetermined paths. For example, a cutting tool cuts the combination of the substrate and the wafer into a plurality of semiconductor elements along the scribe lines preformed on the wafer or along the cutting marks preformed on the substrate.

In yet another preferred embodiment, the method for fabricating semiconductor elements may further comprise a step of testing the electric performance of semiconductor elements. Besides, the method for fabricating semiconductor elements may also comprise a step of encapsulating semiconductor elements, which can prevent the semiconductor elements from the penetration of humidity.

Refer to FIG. 4. In still another preferred embodiment, a BAG (Ball Grid Array) 700 functioning as I/O terminals is preformed on the lower surface 100b of the substrate 100. In the same presorted embodiment, the substrate 100 is a PCB (Printed Circuit Board), and the resin 300 is epoxy.

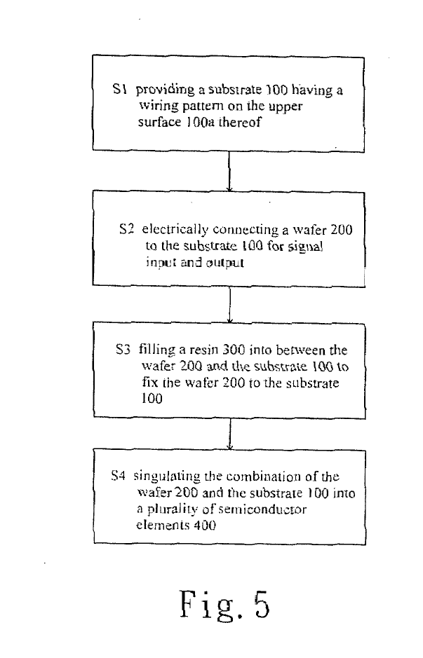

Refer to FIG. 5 a flowchart of the method for fabricating semiconductor elements according to FIGS. 2a-2d. The method for fabricating semiconductor elements of the present invention comprises steps: providing a substrate 100 having a wiring pattern on the upper surface 110a thereof (S1); electrically connecting a wafer 200 to the substrate 100 for signal input and output (S2); filling a resin 300 into between the wafer 200 and the substrate 100 to fox the wafer 200 to the substrate 100 (S3); and singulating the combination of the water 200 and the substrate 100 into a plurality of semiconductor elements 400 (S4).

In the method for fabricating semiconductor elements of the present invention, a wafer is directly stuck to and electrically connected to a substrate, and the wafer and the substrate are simultaneously singulated, whereby the fabrication process is simplified. As a wafer is directly stuck to and electrically connected to a substrate, the fabrication process of the present invention is exempted from sticking chips to the substrate one by one. Therefore, the present invention can save the time and cost of cutting wafers and sticking chips.

The embodiments described above are to demonstrate the technical contents and characteristics of the present invention to enable the persons skilled in the art to understand, make, and use the present invention. However, it is not intended to limit the scope of the present invention. Therefore, any equivalent modification or variation according to the spirit of the present invention is to be also included within the scope of the present invention.

What is claimed is:

1. A method for fabricating semiconductor elements comprising:
providing a substrate having a wiring pattern on an upper surface thereof;
electrically connecting a wafer to said substrate for signal input and output;
filling a resin into between said wafer and said substrate to fix said wafer to said substrate; and
singulating combination of said wafer and said substrate into a plurality of semiconductor elements.

2. The method for fabricating semiconductor elements according to claim 1, wherein said wiring pattern has a plurality of contact pads, and said wafer has a layer of arrayed circuits and a plurality of metal bumps.

3. The method for fabricating semiconductor elements according to claim 2, wherein said contact pads are joined to said metal bumps with a thermal fusion method.

4. The method for fabricating semiconductor elements according to claim 1, wherein said substrate is a printed circuit board.

5. The method for fabricating semiconductor elements according to claim 1 further comprising a step of testing electric performance of said semiconductor elements.

6. The method for fabricating semiconductor elements according to claim 1 further comprising a step of encapsulating said semiconductor elements.

7. The method for fabricating semiconductor elements according to claim 1, wherein a plurality of scribe lines is formed on said water, and said combination of said wafer and said substrate is singulated along said scribe lines.

8. The method for lubricating semiconductor elements according to claim 1, wherein a plurality of cutting marks is formed on said substrate, and said combination of said wafer and said substrate is stimulated along said cutting marks.

9. The method for fabricating semiconductor elements according to claim 1, wherein said resin is filled into between said substrate and said wafer by pressurization.

10. The method for fabricating semiconductor elements according to claim 1, wherein said resin is a high-permittivity polymer or a high-thermal conductivity polymer.

11. The method for fabricating semiconductor elements according to claim 1, wherein said combination of said substrate and said wafer is singulated with a laser or a cutting tool.

12. The method for fabricating semiconductor elements according to claim 1, wherein a ball grid array functioning as input/output terminals is formed on a lower surface of said substrate.
